(19) United States
(12) Patent Application Publication
(10) Pub. No.: US 2026/0305217 A1
(43) Pub. Date: Oct. 1, 2026

(54) METHOD FOR CLEANING SEMICONDUCTOR WAFER

(71) Applicant: SUMCO Corporation, Tokyo (JP)

(72) Inventor: Momoka YAMANAKA, Tokyo (JP)

(73) Assignee: SUMCO Corporation, Tokyo (JP)

(21) Appl. No.: 19/484,247

(22) PCT Filed: Jan. 11, 2024
(86) PCT No.: PCT/JP2024/000494

§ 371 Date: Nov. 13, 2025

(30) Foreign Application Priority Data
May 24, 2023 (JP) 2023-085618

(51) Int. Cl. H10P 70/00

(52) U.S. Cl. CPC H10P 70/15

(57) ABSTRACT

A method for cleaning a semiconductor wafer capable of reducing adhesion-type particles on the surface of the semiconductor wafer. The method includes, while rotating the semiconductor wafer: a first cleaning process of cleaning the semiconductor wafer; a first drying process of drying the semiconductor wafer after the first cleaning process; a second cleaning process of cleaning the semiconductor wafer after the first drying process; and a second drying process of drying the semiconductor wafer after the second cleaning process, wherein the second cleaning process comprises, in the following order: a pure water supplying process; a second initial ozone cleaning process; and a second alternating cleaning process alternately using: a second hydrofluoric acid cleaning process; and a second ozone cleaning process.

### TECHNICAL FIELD

The present disclosure relates to a method for cleaning a semiconductor wafer.

### BACKGROUND

Conventionally, semiconductor wafers such as silicon wafers have been used as substrates for semiconductor devices. A semiconductor wafer is obtained by subjecting a single-crystal ingot grown by the Czochralski (CZ) method or the like to wafer processing. During this processing, particles such as polishing powders adhere to the surface of the semiconductor wafer, and therefore a cleaning process is performed on the semiconductor wafer after the processing to remove such particles.

It is known that in the cleaning process of a semiconductor wafer, particles adhering to the surface of the wafer can be efficiently cleaned and removed by cleaning the wafer surface using various cleaning solutions. For example, Patent Document 1 discloses a method in which ozone cleaning is performed by supplying an ozone solution to the surface of the semiconductor wafer, followed by hydrofluoric acid cleaning by supplying hydrofluoric acid to the wafer surface, and then drying the semiconductor wafer.

### CITATION LIST

### Patent Literature

PTL 1: JP H8-181137 A

### SUMMARY

### Technical Problem

However, in substrates cleaned by such a cleaning method, adhesion-type particles such as polishing powders that could not be completely removed during the cleaning process may remain on the surface of the dried substrate, resulting in insufficient cleaning. The present disclosure aims to provide a method for cleaning a semiconductor wafer that can further reduce the number of residual particles on the surface of the semiconductor wafer.

### Solution to Problem

In order to solve the above problem, the inventors of the present disclosure conducted intensive studies. When a semiconductor wafer is cleaned using a conventional cleaning method, adhesion-type particles remain on the surface of the substrate after drying. As a result, when the surface of the cleaned semiconductor wafer is inspected using a surface inspection apparatus (e.g., Surfscan SP5 or later models manufactured by KLA Corporation), a large number of light point defects (LPDs), presumed to be caused by adhesion-type particles, are detected. Accordingly, the inventors conducted a detailed examination of various methods for cleaning semiconductor wafers and investigated the relationship between such methods and the number of LPDs detected on the surface of the cleaned semiconductor wafer. As a result, they discovered that in order to efficiently remove adhesion-type particles from the semiconductor wafer, it is effective to temporarily stop the cleaning process during the course of multiple cleaning treatments using cleaning solutions, perform a drying process on the semiconductor wafer, subsequently supply pure water, and then resume the cleaning process. This sequence was found to significantly reduce the number of LPDs caused by adhesion-type particles. The gist of the present disclosure, which was completed based on the above findings, is as follows.

(1) A method for cleaning a semiconductor wafer, comprising, while rotating the semiconductor wafer:
a first cleaning process of cleaning the semiconductor wafer;
a first drying process of drying the semiconductor wafer after the first cleaning process;
a second cleaning process of cleaning the semiconductor wafer after the first drying process; and
a second drying process of drying the semiconductor wafer after the second cleaning process,
wherein the first cleaning process comprises, in the following order:
   a first initial ozone cleaning process of supplying an ozone solution to a surface of the semiconductor wafer to perform cleaning; and
   a first alternating cleaning process alternately using: a first hydrofluoric acid cleaning process of cleaning the surface of the semiconductor wafer with an aqueous solution of hydrofluoric acid; and a first ozone cleaning process of cleaning the surface with an ozone solution, following the first hydrofluoric acid cleaning process, and wherein the second cleaning process comprises, in the following order:
   a pure water supplying process of supplying pure water to the surface of the semiconductor wafer after the first drying process;
   a second initial ozone cleaning process of supplying an ozone solution to the surface of the semiconductor wafer to perform cleaning; and
   a second alternating cleaning process alternately using: a second hydrofluoric acid cleaning process of cleaning the surface of the semiconductor wafer with an aqueous solution of hydrofluoric acid; and a second ozone cleaning process of cleaning the surface with an ozone solution, following the second hydrofluoric acid cleaning process.

(2) The method for cleaning a semiconductor wafer according to (1), wherein the number of times the alternating cleaning process is additionally performed in the first cleaning process is not less than one and not more than four.

(3) The method for cleaning a semiconductor wafer according to (1) or (2), wherein the number of times the alternating cleaning process is additionally performed in the first cleaning process is not less than one and not more than two.

(4) The method for cleaning a semiconductor wafer according to (1) or (3), wherein the number of times the alternating cleaning process is additionally performed in the second cleaning process is one.

(5) The method for cleaning a semiconductor wafer according to any one of (1) to (4), wherein a rotation speed of the semiconductor wafer in the pure water supplying process is not less than 25 rpm and not more than 100 rpm.

### Advantageous Effect

According to the present disclosure, adhesion-type particles on the surface of a semiconductor wafer can be reduced.

### BRIEF DESCRIPTION OF THE DRAWINGS

In the accompanying drawings:

FIG. 1 is a flowchart illustrating essential steps in the flow of the method for cleaning a semiconductor wafer according to the present disclosure; and

FIG. 2. is a graph presenting the number of LPDs for Example and Comparative Example.

### DETAILED DESCRIPTION

### (Method for Cleaning a Semiconductor Wafer)

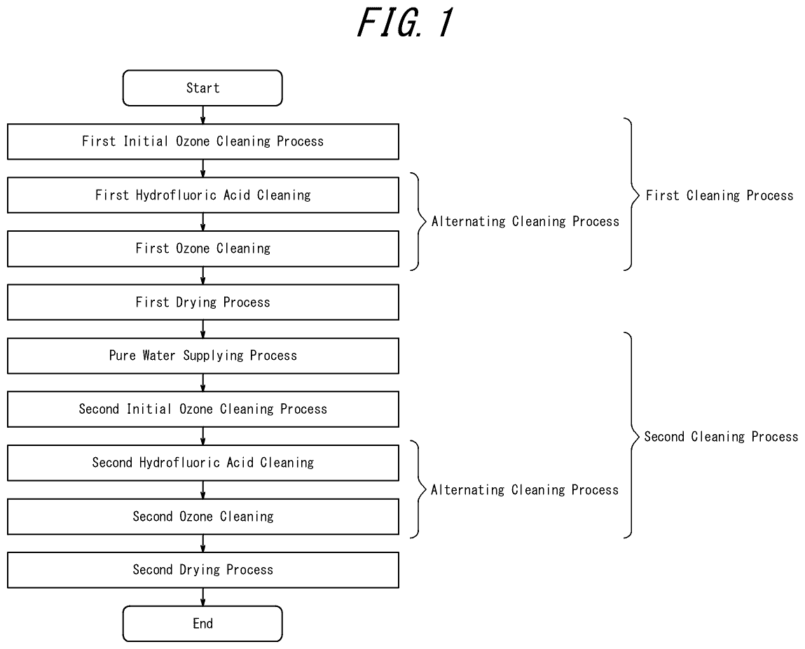

Hereinafter, an embodiment of the present disclosure will be described with reference to FIG. 1. The method for cleaning a semiconductor wafer according to the present disclosure includes, at least while rotating the semiconductor wafer: a first cleaning process of cleaning the semiconductor wafer; a first drying process of drying the semiconductor wafer after the first cleaning process; a second cleaning process of cleaning the semiconductor wafer after the first drying process; and a second drying process of drying the semiconductor wafer after the second cleaning process. In the first cleaning process, the initial ozone cleaning process is particularly referred to as the first “initial” ozone cleaning process, and is distinguished from a first hydrofluoric acid cleaning process and a first ozone cleaning process that are subsequently repeated. Similarly, in the second cleaning process, the initial ozone cleaning is particularly referred to as the second “initial” ozone cleaning process, and is distinguished from a second hydrofluoric acid cleaning process and a second ozone cleaning process that are subsequently repeated. The details of each process are described below.

### <First Cleaning Process>

The first cleaning process comprises, in the following order: a first initial ozone cleaning process of supplying an ozone solution to a surface of the semiconductor wafer to perform cleaning; and a first alternating cleaning process alternately using: the first hydrofluoric acid cleaning process of cleaning the surface of the semiconductor wafer with an aqueous solution of hydrofluoric acid; and the first ozone cleaning process of cleaning the surface with an ozone solution, following the first hydrofluoric acid cleaning process. Each of these processes will be described in order below.

### «First Initial Ozone Cleaning Process»

In the first initial ozone cleaning process, the semiconductor wafer is rotated while an ozone solution is supplied to the surface of the semiconductor wafer to perform ozone cleaning on the surface thereof. In this process, metals and organic substances adhering to the surface of the semiconductor wafer can be oxidized and removed, and an oxide film can be formed beneath other adhesion-type particles remaining on the surface of the semiconductor wafer. It is also preferable that, prior to the first initial ozone cleaning process, pure water is preliminarily supplied to the surface of the semiconductor wafer so that the surface is in a wet state.

### «First Hydrofluoric Acid Cleaning Process and First Ozone Cleaning Process»

In this process, the surface of the semiconductor wafer is alternately cleaned by the first hydrofluoric acid cleaning process of cleaning the surface of the semiconductor wafer with an aqueous solution of hydrofluoric acid, and the first ozone cleaning process of cleaning the surface with an ozone solution, following the first hydrofluoric acid cleaning process. In the first hydrofluoric acid cleaning process and the first ozone cleaning process, the semiconductor wafer, which has undergone the first initial ozone cleaning process, is first subjected to the first hydrofluoric acid cleaning process, in which the semiconductor wafer is rotated while an aqueous solution of hydrofluoric acid (hydrogen fluoride: HF) is supplied to the surface to perform hydrofluoric acid cleaning. Then, in the subsequent first ozone cleaning, the hydrofluoric-acid-cleaned semiconductor wafer is rotated while an ozone solution is supplied to the surface to perform ozone cleaning process. In the first hydrofluoric acid cleaning process and the first ozone cleaning process, the oxide film formed in the first initial ozone cleaning process can be removed, and, in the course of this removal, metals and particles adhering to the surface of the semiconductor wafer can also be removed.

In the alternating cleaning process alternately using the first hydrofluoric acid cleaning process and the first ozone cleaning process, it is preferable to additionally perform the first hydrofluoric acid cleaning process and the first ozone cleaning process alternately a predetermined number of times. It is preferable that the number of times the alternating cleaning process is additionally performed in the first cleaning process be set within a range of not less than one and not more than four, and more preferably within a range of not less than one and not more than two. Note that, in this specification, “additionally performed” refers to the number of times performed in addition to the one mandatory cycle. That is, the total number of times the alternating cleaning process is performed in the first cleaning process is preferably within a range of not less than two and not more than five, and more preferably within a range of not less than two and not more than three.

### «First Drying Process»

In the first drying process, the semiconductor wafer, after the first ozone cleaning in the first cleaning process, is rotated at high speed to perform spin drying while continuing to rotate the semiconductor wafer. In this first drying process, the rotation speed of the semiconductor wafer may be, for example, not less than 1000 rpm and not more than 2000 rpm. By performing this first drying process, adhesion-type particles that could not be removed in the first cleaning process can be brought into a state in which they are more easily detached by reducing the adhesive force between the particles and the semiconductor wafer.

### <Second Cleaning Process>

The second cleaning process comprises, in the following order: a pure water supplying process of supplying pure water to the surface of the semiconductor wafer after the first drying process; a second initial ozone cleaning process of supplying an ozone solution to the surface of the semiconductor wafer to perform cleaning; and a second alternating cleaning process alternately using: a second hydrofluoric acid cleaning process of cleaning the surface of the semiconductor wafer with an aqueous solution of hydrofluoric acid; and a second ozone cleaning process of cleaning the surface with an ozone solution, following the second hydrofluoric acid cleaning process. Each of these processes will be described below in order.

### «Pure Water Supplying Process»

First, at the beginning of the second cleaning process, a pure water supplying process is performed. In the pure water supplying process, it is preferable to supply pure water at a low flow rate using a vertical nozzle while the semiconductor wafer is rotating at a low speed. By performing the pure water supplying process, it is preferable to supply pure water to the central portion of the surface of the semiconductor wafer while rotating the wafer. Supplying pure water to the central portion of the rotating semiconductor wafer allows the pure water to spread uniformly across the entire wafer from the center toward the periphery due to centrifugal force, thereby forming a pure water film on the surface of the semiconductor wafer.

By forming a pure water film on the surface of the semiconductor wafer, when the supply is switched from pure water to a cleaning solution, the cleaning solution is diluted by the pure water present on the surface of the semiconductor wafer, thereby lowering its reactivity and suppressing turbulence caused by the high concentration of the cleaning solution at the initial stage of its supply. As a result, the cleaning solution can spread uniformly over the entire surface of the semiconductor wafer at a uniform concentration, allowing the surface of the semiconductor wafer to be cleaned uniformly.

It is preferable that the supply of pure water be continued at least until a pure water film is formed over the entire surface of the semiconductor wafer. In the present disclosure, it is also preferable to continue supplying pure water to the surface of the semiconductor wafer until the subsequent second initial ozone cleaning, in which the supply is switched to an ozone solution.

The purity of the pure water supplied to the surface of the semiconductor wafer is not particularly limited as long as it has a level of purity sufficient to achieve the required product quality. The purity of the pure water may be at a so-called pure water level (for example, a resistivity of not less than 0.1 MΩ·cm and not more than 15 MΩ·cm), or may be at an ultrapure water level (for example, a resistivity exceeding 15 MΩ·cm).

It is preferable that the pure water be supplied in the pure water supplying process while the semiconductor wafer is being rotated at a rotation speed of not less than 25 rpm and not more than 100 rpm. This prevents turbulence of the pure water caused by a water-splashing phenomenon, and also prevents turbulence of the hydrofluoric acid cleaning solution in the subsequent second cleaning process even when the hydrofluoric acid cleaning solution is supplied, thereby allowing the surface of the semiconductor wafer to be cleaned more uniformly.

### «Second Initial Ozone Cleaning Process»

In the second initial ozone cleaning process, the semiconductor wafer supplied with pure water is rotated while an ozone solution is supplied to the surface of the semiconductor wafer to perform ozone cleaning on the surface. Similar to the first initial ozone cleaning process in the first cleaning process, this process allows metals and organic substances adhering to the surface of the semiconductor wafer to be oxidized and removed, and enables the formation of an oxide film beneath other adhesion-type particles adhering to the surface of the semiconductor wafer.

### «Second Hydrofluoric Acid Cleaning Process and Second Ozone Cleaning Process»

In this process, the surface of the semiconductor wafer is alternately cleaned by a second hydrofluoric acid cleaning process of cleaning the surface of the semiconductor wafer with an aqueous solution of hydrofluoric acid; and a second ozone cleaning process of cleaning the surface with an ozone solution, following the second hydrofluoric acid cleaning process. In the second hydrofluoric acid cleaning process and the second ozone cleaning process, the semiconductor wafer, after the second initial ozone cleaning process following the pure water supplying process, is first rotated while an aqueous solution of hydrofluoric acid is supplied to the surface of the semiconductor wafer to perform hydrofluoric acid cleaning. Then, in the subsequent second ozone cleaning, the hydrofluoric-acid-cleaned semiconductor wafer is rotated while an ozone solution is supplied to the surface of the semiconductor wafer to perform ozone cleaning.

When the rotation speed of the semiconductor wafer after the second initial ozone cleaning process is set higher than the rotation speed in the pure water supplying process, it is preferable to increase the rotation speed of the semiconductor wafer after the pure water on the surface of the wafer has been completely replaced by the ozone solution following the switch from pure water supply to ozone solution supply.

Most of the particles on the surface of the semiconductor wafer are removed by the first cleaning process, but some particles remain as adhesion-type particles. These adhesion-type particles are not strongly fixed to the surface of the semiconductor wafer, but are considered to have become more easily detachable due to the first drying process following the first cleaning process. Therefore, by performing the second cleaning process on the surface of the semiconductor wafer after the first drying process, the cleaning solution can further penetrate beneath the remaining adhesion-type particles on the wafer surface, making it possible to remove these particles.

The alternating cleaning process alternately using the second hydrofluoric acid cleaning process and the second ozone cleaning process can be configured to repeat the second hydrofluoric acid cleaning process and the second ozone cleaning process alternately a predetermined number of times. It is preferable that the rotation speed of the semiconductor wafer during the supply of the aqueous solution of hydrofluoric acid be not less than 50 rpm and not more than 800 rpm, and more preferably not less than 300 rpm and not more than 500 rpm. It is also preferable that the aqueous solution of hydrofluoric acid be supplied at a flow rate of not less than 0.5 L/min and not more than 1.5 L/min, and that its concentration be not less than 0.5 wt % and not more than 3.0 wt %. Similarly, it is preferable that the rotation speed of the semiconductor wafer during the supply of the ozone solution be not less than 50 rpm and not more than 800 rpm, and more preferably not less than 300 rpm and not more than 500 rpm. The ozone solution is preferably supplied at a flow rate of not less than 0.5 L/min and not more than 2.0 L/min, and more preferably at a flow rate of not less than 1.0 L/min and not more than 2.0 L/min. It is also preferable that the ozone concentration be not less than 20 mg/L and not more than 30 mg/L. By setting these parameters within the above ranges, the surface of the semiconductor wafer can be cleaned uniformly.

In the alternating cleaning process alternately using the second hydrofluoric acid cleaning process and the second ozone cleaning process, it is preferable to additionally perform the second hydrofluoric acid cleaning process and the second ozone cleaning process alternately a predetermined number of times. It is preferable that the number of times the alternating cleaning process is additionally performed in the second cleaning process be one. That is, it is preferable that the alternating cleaning process be performed a total of two times in the second cleaning process.

### «Second Drying Process»

Finally, the semiconductor wafer that has undergone the alternating cleaning process alternately using the second hydrofluoric acid cleaning process and the second ozone cleaning process is rotated at high speed to perform spin drying. Although the drying conditions in the second drying process are not particularly limited, it is preferable that the rotation speed of the semiconductor wafer be not less than 1000 rpm and not more than 2000 rpm, and that the drying time be not less than 25 seconds and not more than 40 seconds. It is also permissible to perform a rinsing process before the second drying process by supplying pure water to the surface of the rotating semiconductor wafer.

Thus, by using the semiconductor wafer cleaning method according to the present embodiment, adhesion-type particles on the surface of the semiconductor wafer can be reduced. The semiconductor wafer to be cleaned by the present disclosure may be any type of semiconductor wafer, such as a silicon wafer, a germanium wafer, or a gallium arsenide wafer. Among them, the present disclosure is particularly suitable for cleaning silicon wafers. The semiconductor wafer may be a single-crystal wafer or a polycrystalline wafer. Furthermore, the semiconductor wafer may be an epitaxial wafer or an annealed wafer. There are no particular limitations on the diameter, conductivity type, or resistivity of the semiconductor wafer.

### EXAMPLES

Examples of the present disclosure will be described below; however, the present disclosure is not limited to these examples.

### Comparative Example 1

In Comparative Example 1, eight silicon wafers with a diameter of 300 mm were prepared, and each silicon wafer was subjected to a cleaning process using a spin cleaning apparatus. Specifically, first, each silicon wafer was rotated while an ozone solution was supplied to the surface of the silicon wafer to perform ozone cleaning process. Next, an aqueous solution of hydrofluoric acid was supplied to the surface of the silicon wafer to perform hydrofluoric acid cleaning process, followed by ozone cleaning process again. This alternating cleaning process was repeated a total of three times (i.e., the number of additional repetitions was two). The conditions for each ozone cleaning process (wafer rotation speed, ozone concentration, flow rate, and duration) were kept the same, and the conditions for each hydrofluoric acid cleaning process (wafer rotation speed, HF concentration, flow rate, and duration) were also kept the same. After the final ozone cleaning process, the wafer was dried by spinning it at high speed. In this manner, the silicon wafers of Comparative Example 1 were obtained.

### Comparative Example 2

In Comparative Example 2, eight silicon wafers with a diameter of 300 mm were prepared, and each silicon wafer was subjected to a cleaning process using a spin cleaning apparatus. Except that the alternating cleaning operation of hydrofluoric acid cleaning process followed by ozone cleaning process was performed a total of five times (i.e., the number of additional repetitions was four), all other process conditions were the same as those in Comparative Example 1. In this manner, the silicon wafers of Comparative Example 2 were obtained.

### Example

In the Example, eight silicon wafers with a diameter of 300 mm were prepared, and each silicon wafer was subjected to a cleaning process using a spin cleaning apparatus. Specifically, first, each silicon wafer was rotated while an ozone solution was supplied to the surface of the silicon wafer to perform ozone cleaning process. Next, an aqueous solution of hydrofluoric acid was supplied to the surface of the ozone-cleaned silicon wafer to perform hydrofluoric acid cleaning process, followed by ozone cleaning process again. This alternating cleaning operation was repeated a total of three times (i.e., the number of additional repetitions was two). Subsequently, after the final ozone cleaning process, the silicon wafer was dried by spinning it at high speed. Then, while slowly rotating the dried silicon wafer at a rotation speed of 50 rpm, pure water was supplied to the surface of the silicon wafer to perform a rinsing process. Thereafter, ozone cleaning process was performed by supplying an ozone solution to the surface of the silicon wafer that had undergone the pure water supplying process. Then, an aqueous solution of hydrofluoric acid was supplied to perform hydrofluoric acid cleaning process, followed by ozone cleaning process again. This alternating cleaning operation was performed a total of two times (i.e., the number of additional repetitions was one).

In this manner, the silicon wafers of Example were obtained. The conditions for each ozone cleaning process (wafer rotation speed, ozone concentration, flow rate, and duration) were the same as those in Comparative Examples 1 and 2, and the conditions for the hydrofluoric acid cleaning process (wafer rotation speed, hydrofluoric acid concentration, flow rate, and duration) were also the same as those in Comparative Examples 1 and 2.

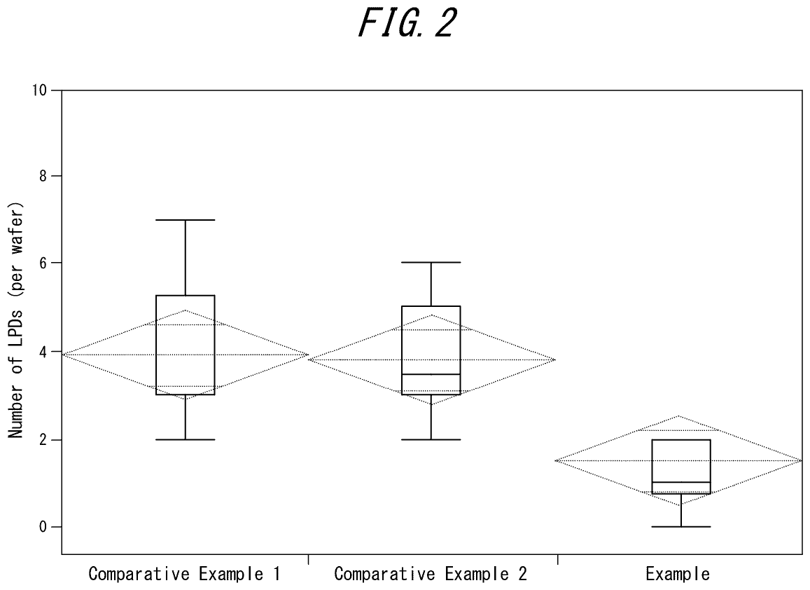

For Comparative Examples 1 and 2 and Example, the surfaces of each of the eight cleaned silicon wafers were inspected using a surface inspection apparatus (Surfscan SP7 manufactured by KLA Corporation). In the inspection, oblique incident light (incident at an angle of 70 degrees relative to the normal direction of the wafer surface) was used as the incident light to the surface of the silicon wafer, and the DCO channel was used as the detection channel. LPDs (light point defects) with a size of 15 nm or greater were detected. The results are given in FIG. 2.

In Comparative Example 1, the number of LPDs per silicon wafer was 3.9. In Comparative Example 2, despite increasing the number of repeated cleaning cycles compared to Comparative Example 1, the number of LPDs per silicon wafer was 3.8, which was almost the same as in Comparative Example 1, and no improvement effect was observed. In contrast, in Example, the number of LPDs per silicon wafer was reduced to 1.5. That is, it was found that temporarily stopping the repeated cleaning operation on the semiconductor wafer, performing a drying process, then supplying pure water, and subsequently resuming the repeated cleaning operation resulted in a significant reduction in LPDs caused by adhesion-type particles.

### INDUSTRIAL APPLICABILITY

According to the present disclosure, adhesion-type particles on the surface of a semiconductor wafer can be reduced, and thus the disclosure is useful in the semiconductor wafer manufacturing industry.

1-5. (canceled)

6. A method for cleaning a semiconductor wafer, comprising, while rotating the semiconductor wafer:
a first cleaning process of cleaning the semiconductor wafer;
a first drying process of drying the semiconductor wafer after the first cleaning process;
a second cleaning process of cleaning the semiconductor wafer after the first drying process; and
a second drying process of drying the semiconductor wafer after the second cleaning process,
wherein the first cleaning process comprises, in the following order:
a first initial ozone cleaning process of supplying an ozone solution to a surface of the semiconductor wafer to perform cleaning; and
a first alternating cleaning process alternately using: a first hydrofluoric acid cleaning process of cleaning the surface of the semiconductor wafer with an aqueous solution of hydrofluoric acid; and a first ozone cleaning process of cleaning the surface with an ozone solution, following the first hydrofluoric acid cleaning process, and
wherein the second cleaning process comprises, in the following order:
a pure water supplying process of supplying pure water to the surface of the semiconductor wafer after the first drying process;
a second initial ozone cleaning process of supplying an ozone solution to the surface of the semiconductor wafer to perform cleaning; and
a second alternating cleaning process alternately using: a second hydrofluoric acid cleaning process of cleaning the surface of the semiconductor wafer with an aqueous solution of hydrofluoric acid; and a second ozone cleaning process of cleaning the surface with an ozone solution, following the second hydrofluoric acid cleaning process.

7. The method for cleaning a semiconductor wafer according to claim 6, wherein the number of times the alternating cleaning process is additionally performed in the first cleaning process is not less than one and not more than four.

8. The method for cleaning a semiconductor wafer according to claim 6, wherein the number of times the alternating cleaning process is additionally performed in the first cleaning process is not less than one and not more than two.

9. The method for cleaning a semiconductor wafer according to claim 7, wherein the number of times the alternating cleaning process is additionally performed in the first cleaning process is not less than one and not more than two.

10. The method for cleaning a semiconductor wafer according to claim 6, wherein the number of times the alternating cleaning process is additionally performed in the second cleaning process is one.

11. The method for cleaning a semiconductor wafer according to any one of claim 6, wherein a rotation speed of the semiconductor wafer in the pure water supplying process is not less than 25 rpm and not more than 100 rpm.
